(19) United States
(12) Patent Application Publication
(10) Pub. No.: US 2013/0002109 A1
(43) Pub. Date: Jan. 3, 2013

(54) Mobile Electronic Device Housing

(76) Inventor: Peter Benjamin Gloria, Los Angeles, CA (US)

(21) Appl. No.: 13/540,506

(22) Filed: Jul. 2, 2012

Related U.S. Application Data
(60) Provisional application No. 61/503,180, filed on Jun. 30, 2011.

(51) Int. Cl. H05K 5/02; B23P 11/00

(52) U.S. Cl. 312/244; 29/428

(57) ABSTRACT

A mobile electronic device housing includes a housing base including a sound redirection chamber, a locking slide cavity, and a support handle cavity. The mobile electronic device housing further includes a housing front panel configured to couple to the housing base including a rectangular top opening, a push button, a locking slide receiver and a sound redirection vent. The mobile electronic device housing further includes a locking slide coupled to the locking slide. The mobile electronic device housing further includes a support handle coupled to the support handle cavity.

The present application claims priority to U.S. Provisional Application Ser. No. 61/503,180, filed on Jun. 30, 2011, which is herein incorporated by reference for completeness of disclosure.

### BACKGROUND OF THE INVENTION

1. Field of the Invention

The present invention relates to the field of electronic device housings.

2. Description of the Related Art

Mobile electronic devices such as tablet computers and mobile phones are widely used in educational, commercial, and industrial environments. These mobile electronic devices are typically multipurpose and run a variety of software applications to accomplish various tasks. Typical mobile electronic devices allow a user to browse web pages, work with email, play games, listen to music, read electronic books, and more.

Such mobile electronic devices have revolutionized the education field by running various educational software applications in a convenient and attractive form factor. However, the versatility of the mobile electronic devices often makes it difficult for educators to focus users of the mobile electronic devices on specific software applications. Many tablet computers and mobile phones have a physical button that may be pushed to allow a user to easily switch between software applications. Most mobile electronic devices do not include physical security features that prevent users from switching between software applications.

Typical mobile electronic devices include speakers for sound output, but such speakers are often located towards the rear of such devices due to space or design constrictions. Speakers located towards the rear have the side effect of degrading both sound quality and volume.

Therefore, there is a need for a mobile electronic device housing to provide physical security features while enhancing both functionality and ease of use.

### BRIEF SUMMARY OF THE INVENTION

One or more embodiments of the invention enable a mobile electronic device housing. In some exemplary embodiments of the present invention, a mobile electronic device housing includes a housing base including a sound redirection chamber, a locking slide cavity, and a support handle cavity. The mobile electronic device housing further includes a housing front panel configured to couple to the housing base including a rectangular top opening, a push button, a locking slide receiver and a sound redirection vent. The mobile electronic device housing further includes a locking slide coupled to the locking slide receiver and configured to selectively toggle between a button locked position and a button free position in relation to the locking slide receiver with a linear range of motion parallel to a longitudinal axis from a top end of the housing front panel to a bottom end of the housing front panel. The mobile electronic device housing further includes a support handle coupled to the support handle cavity by a set of pivots on the support handle to a set of notches from a plurality of notches on the support handle cavity and configured to selectively toggle between a plurality of locking positions in relation to the support handle cavity.

In some exemplary embodiments of a mobile electronic device housing, the functionality of the housing base and the housing front panel may be combined into an enclosure body. The enclosure body may be opened to allow insertion of the specific mobile electronic device then closed to disallow displacement of the specific mobile electronic device within the enclosure body.

In some exemplary embodiments of a mobile electronic device housing, the housing base comprises at least one housing base peripheral opening based on the location of at least one peripheral port on the specific mobile electronic device

In some exemplary embodiments of a mobile electronic device housing, the support handle cavity comprises at least three (3) sets of notches corresponding to at least five (5) selectable support handle positions.

### BRIEF DESCRIPTION OF THE DRAWINGS

The above and other aspects, features and advantages of the invention will be more apparent from the following more particular description thereof, presented in conjunction with the following drawings wherein:

FIG. 1 illustrates an exemplary embodiment of a mobile electronic device housing;

FIG. 2 is an exploded perspective view of one or more exemplary embodiments of a mobile electronic device housing;

FIG. 3 is a second exploded perspective view of one or more exemplary embodiments of a mobile electronic device housing;

FIG. 4 illustrates an exemplary embodiment of a mobile electronic device housing in a button free position; and

FIG. 5 illustrates an exemplary embodiment of a mobile electronic device housing in a button locked position.

### DETAILED DESCRIPTION

A mobile electronic device housing will now be described. In the following exemplary description numerous specific details are set forth in order to provide a more thorough understanding of embodiments of the invention. It will be apparent, however, to an artisan of ordinary skill that the present invention may be practiced without incorporating all aspects of the specific details described herein. In other instances, specific features, quantities, or measurements well known to those of ordinary skill in the art have not been described in detail so as not to obscure the invention. Readers should note that although examples of the invention are set forth herein, the claims, and the full scope of any equivalents, are what define the metes and bounds of the invention.

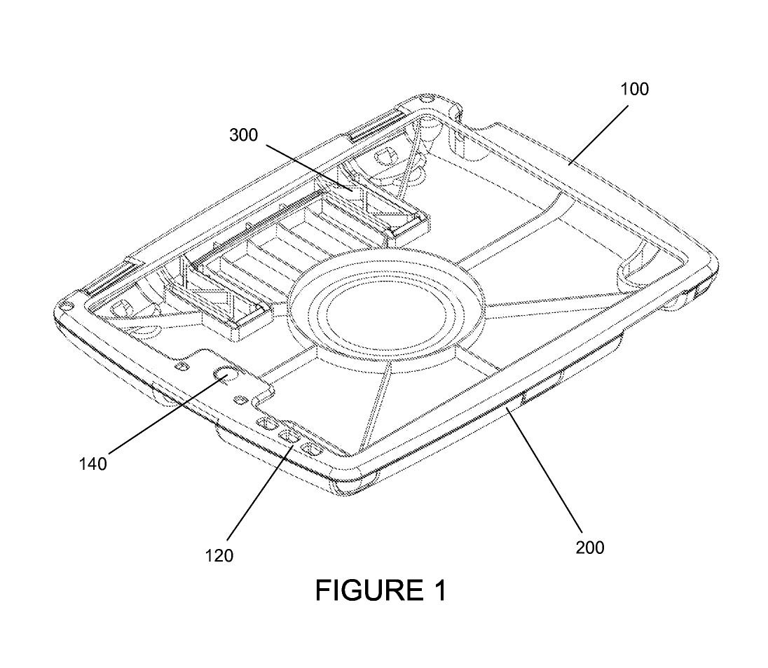

FIG. 1 illustrates an exemplary embodiment of a mobile electronic device housing. Some exemplary embodiments of a mobile electronic device housing comprises a housing base 200 and a housing front panel 100 configured to couple to the housing base 200. The housing front panel 100 may comprise any sturdy and aesthetically pleasing material such as wood, metal, fiberglass, plastic, rubber, ethylene vinyl acetate, and polystyrene foam. The housing base 200 may comprise any sturdy material such as wood, metal, fiberglass, plastic, rubber, and ethylene vinyl acetate.

In some exemplary embodiments of a mobile electronic device housing, the housing front panel 100 may be rectangular frame shaped along a flat plane. The housing base 200 may be rectangular basin shaped with a top side opening facing towards the housing front panel 100. The housing base 200 and housing front panel 100 may have a substantially equal width and length. In some embodiments, coupling the housing base 200 with the housing front panel 100 creates a tablet shaped cavity between the housing base 200 and the housing front panel 100. The width, length, and thickness of the housing base 200 and housing front panel 100 are configured to be slightly larger than a specific mobile electronic device so that the specific mobile electronic device may snuggly fit in the tablet shaped cavity between the housing base 200 and housing front panel 100, disallowing displacement of the specific mobile electronic device. The specific mobile electronic device may be any portable device with a touch screen display including but not limited to electronic tablets, mobile phones, personal computers, and portable media players. The housing front panel 100 may have an opening of width and height substantially equal to a width and height of a touch screen display on the specific mobile electronic device.

In some exemplary embodiments of a mobile electronic device housing, the functionality of the housing base 200 and the housing front panel 100 may be combined into an enclosure body. The enclosure body may be opened to allow insertion of the specific mobile electronic device then closed to disallow displacement of the specific mobile electronic device within the enclosure body.

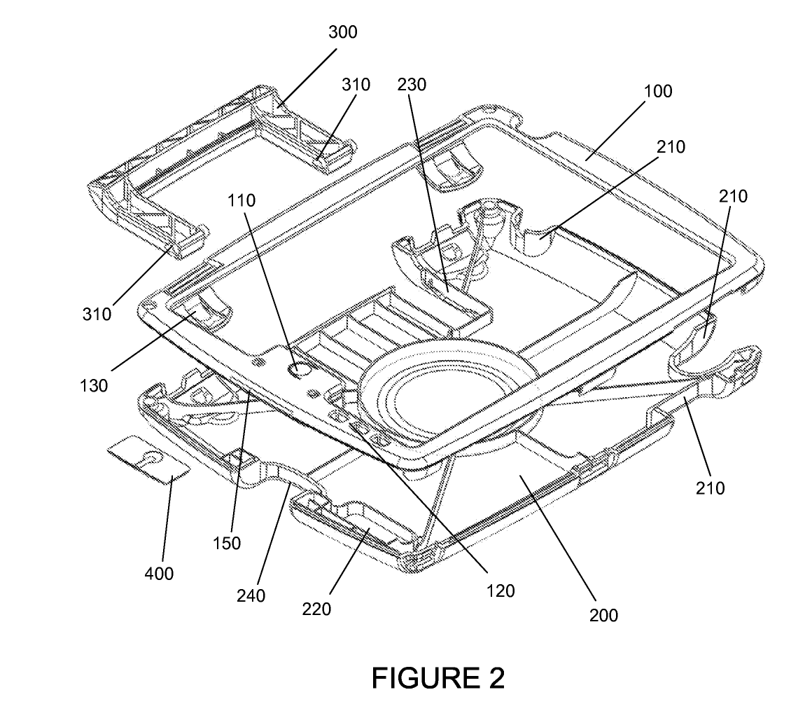

FIG. 2 is an exploded perspective view of one or more exemplary embodiments of a mobile electronic device housing. In some exemplary embodiments, a mobile electronic device housing comprises a housing base 200 including a sound redirection chamber 220, a locking slide cavity 240, and a support handle cavity 230. In some exemplary embodiments, the housing front panel 100 comprises a rectangular top opening, a push button 140, a locking slide receiver 150 and a sound redirection vent 120.

In some exemplary embodiments of a mobile electronic device housing, the position of the push button 140 is positioned above the location of a physical button on the specific mobile electronic device when the specific mobile device is inserted between the housing base 200 and the housing front panel 100. The physical button on the specific mobile device will often have a function of switching between software applications ran on the specific mobile device. This positioning allows a user to press down on the push button 140 which in turn presses down on the physical button on the specific mobile electronic device.

In some exemplary embodiments of a mobile electronic device housing, the sound redirection chamber 220 is a hollow cavity comprising a top opening and a curved wall extending from a top-rear point of the sound redirection chamber 220 to a bottom-front point of the sound redirection chamber 220, wherein the top opening is based on an exterior surface shape corresponding to a speaker portion of a specific mobile electronic device. The mobile electronic device housing of claim 1, wherein the sound redirection vent 120 comprises at least one opening on a top surface of the housing front panel 100. During use, the specific mobile electronic device, when placed between the housing base 200 and housing front panel 100, will have its speaker portion positioned over the sound redirection chamber 220. Audible sound emitting from the speaker portion will reflect against walls of the sound redirection chamber 220 and be redirected towards the housing front panel 100. In this manner, the audible sound that would otherwise travel away from a user of the mobile electronic device would instead travel towards the user when the specific mobile electronic device is used in conjunction with the mobile electronic device housing.

In some exemplary embodiments of a mobile electronic device housing, the housing base 200 comprises at least one housing base peripheral opening 210 based on the location of at least one peripheral port on the specific mobile electronic device. The housing base peripheral opening 210 allows peripheral connectors such as power connectors, headphone connectors, or usb drives to be inserted through the base peripheral opening 210s into the specific mobile electronic device.

In some exemplary embodiments of a mobile electronic device housing, a support handle 300 couples to the support handle cavity 230 by a set of pivots 310 on the support handle 300 to a set of notches from a plurality of notches on the support handle cavity 230 and configured to selectively toggle between a plurality of locking positions in relation to the support handle cavity 230. The different locking positions may each serve different unities to a user. In some exemplary embodiments of a mobile electronic device housing, the support handle 300 may have a U-shaped handle with a flat horizontal section as is commonly used in briefcase handles. The support handle cavity 230 may be configured to have slightly larger dimensions than the support handle 300, allowing the support handle 300 to fully retract within the support handle cavity 230.

In some exemplary embodiments of a mobile electronic device housing, the support handle cavity 230 comprises at least three (3) sets of notches corresponding to at least five (5) selectable support handle positions. A first set of notches corresponds to a first selectable support handle position in which the support handle 300 is fully retracted within the support handle cavity 230 or a second selectable support handle position in which the support handle 300 is perpendicularly extended from the first set of notches. A second set of notches corresponds with a third selectable support handle position in which the support handle 300 extends from the second set of notches at an angle between 25 degrees and 155 degrees to the support handle cavity 230. A third set of notches corresponds to a fourth selectable support handle position in which the support handle 300 is fully extended parallel to the support handle cavity 230 or a fifth selectable support handle position in which the support handle 300 is perpendicularly extended from the third set of notches. The first selectable support handle position allows the support handle 300 to be fully retracted and prepares the mobile electronic device housing for storage. The fourth selectable handle position allows a user to carry the mobile electronic device housing using the support handle 300. The second, third, and fifth selectable handle positions allow the mobile electronic device housing to be propped up at various angles on a resting surface such as a table, allowing the user to view the display screen at a user's preferred viewing angle.

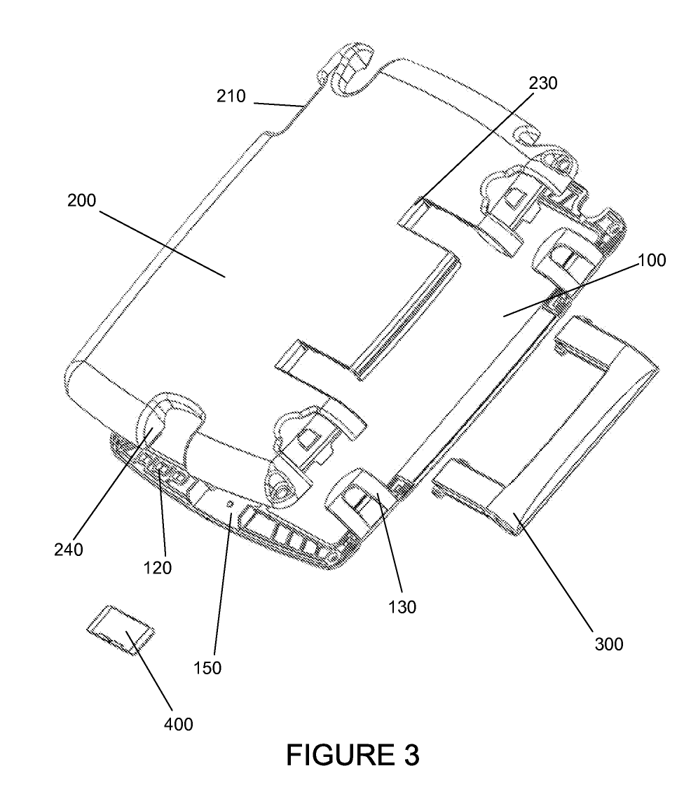

FIG. 3 is a second exploded perspective view of one or more exemplary embodiments of a mobile electronic device housing. In some embodiments of a mobile electronic device housing, the housing front panel 100 is removably coupled to the housing base 200. In some embodiments, a latch hinged to the housing front panel 100 may be used to snap into a notched extrusion on the housing base 200 to removably couple the housing front panel 100 to the housing base 200. It is conceivable that any other coupling mechanism may be used to couple the housing front panel 100 to the housing base 200 including but not limited to fasteners, screws, bolts, adhesives, and spring clips.

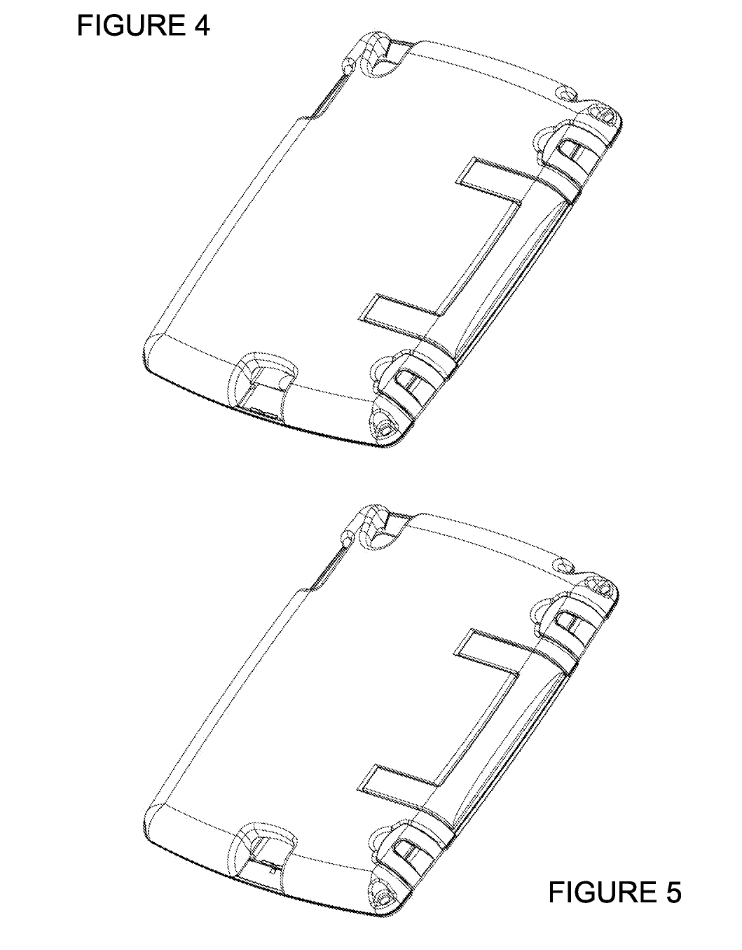

FIG. 4 illustrates an exemplary embodiment of a mobile electronic device housing in a button free position. FIG. 5 illustrates an exemplary embodiment of a mobile electronic device housing in a button locked position. In some embodiments of a mobile electronic device housing, the locking slide receiver 150 is positioned adjacent to the push button 140 on the housing front panel 100. The locking slide cavity 240 may be positioned adjacent said locking slide receiver 150. A locking slide 400 may be of any planar shape such as a rectangular planar shape.

The locking slide receiver 150 is configured allow the locking slide 400 to selectively toggle between a button locked position and a button free position in relation to the locking slide receiver 150 with a linear range of motion parallel to a longitudinal axis from a top end of the housing front panel 100 to a bottom end of the housing front panel 100. The button locked position describes locking slide 400 in a position between the push button 140 and the physical button on the specific mobile electronic device, prevent 120ing a user pushing down on the push button 140 from also pushing the physical button on the specific mobile electronic device. The button free position describes the locking slide 400 in a position not between the push button 140 and the physical button on the specific mobile electronic device, allowing a user to press down on the push button 140 which in turn presses down on the physical button on the specific mobile electronic device.

In some embodiments of a mobile electronic device housing, the locking slide 400 may comprise a raised protrusion or an inward notch configured to facilitate a user's fingers in selectively toggling the locking slide 400. The locking slide cavity 240 is a cutout of the housing base 200 configured to provide space for a user's fingers in selectively toggling the locking slide 400. In some embodiments, the locking slide cavity 240 has a shape and dimensions configured to be substantially similar to the locking slide receiver 150. In some embodiments of a mobile electronic device housing, the locking slide receiver 150 comprises at least one locking slide notch configured to secure the locking slide 400 in the button locked position until greater than the threshold amount of force is applied.

What is claimed is:

1. A mobile electronic device housing, comprising:
a housing base comprising a sound redirection chamber, a locking slide cavity, and a support handle cavity;
a housing front panel configured to couple to said housing base comprising a rectangular top opening, a push button, a locking slide receiver and a sound redirection vent, wherein said push button is located on a top panel surface opposite to said locking slide receiver;
a locking slide coupled to said locking slide receiver configured to selectively toggle between a button locked position and a button free position in relation to said locking slide receiver with a linear range of motion parallel to a longitudinal axis from a top end of said housing front panel to a bottom end of said housing front panel, wherein said locking slide receiver is configured to allow said locking slide to selectively toggle by applying greater than a threshold amount of force to said locking slide along said linear range of motion; and
a support handle coupled to said support handle cavity by a set of pivots on said support handle to a set of notches from a plurality of notches on said support handle cavity and configured to selectively toggle between a plurality of locking positions in relation to said support handle cavity, wherein said support handle cavity is configured to allow said support handle to selectively toggle by rotating said support handle to a retracted angle, then linearly shifting said set of pivots on said support handle to a desired notch from said plurality of notches, then rotating said support handle to a desired angle.

2. The mobile electronic device housing of claim 1, wherein said front panel is removably coupled to said housing base.

3. The mobile electronic device housing of claim 1, wherein said sound redirection chamber is a hollow cavity comprising a top opening and a curved wall extending from a top-rear point of said sound redirection chamber to a bottom-front point of said sound redirection chamber, wherein said top opening is based on an exterior surface shape corresponding to a speaker portion of a mobile electronic device.

4. The mobile electronic device housing of claim 1, wherein said sound redirection vent comprises at least one opening on a top surface of said housing front panel.

5. The mobile electronic device housing of claim 1, wherein said locking slide receiver is positioned adjacent to said push button on said housing front panel, wherein said locking slide cavity is positioned adjacent said locking slide receiver.

6. The mobile electronic device housing of claim 1, wherein said locking slide receiver comprises at least one locking slide notch configured to secure said locking slide in said button locked position until greater than said threshold amount of force is applied.

7. The mobile electronic device housing of claim 1, wherein said housing base comprises at least one housing base peripheral opening based on the location of at least one peripheral port on a mobile electronic device.

8. The mobile electronic device housing of claim 1, wherein said housing front panel comprises wood, metal, glass, fiberglass, plastic, rubber, ethylene vinyl acetate, and/or polystyrene foam.

9. The mobile electronic device housing of claim 1, wherein said support handle cavity comprises at least three (3) sets of notches corresponding to at least five (5) selectable support handle positions,
wherein a first set of notches corresponds to a first selectable support handle position in which said support handle is fully retracted within said support handle cavity or a second selectable support handle position in which said support handle is perpendicularly extended from said first set of notches,
wherein a second set of notches corresponds with a third selectable support handle position in which said support handle extends from said second set of notches at an angle between 25 degrees and 155 degrees to said support handle cavity, and
wherein a third set of notches corresponds to a fourth selectable support handle position in which said support handle is fully extended parallel to said support handle cavity or a fifth selectable support handle position in which said support handle is perpendicularly extended from said third set of notches.

10. A mobile electronic device housing, comprising:
an enclosure body comprising a sound redirection chamber, a locking slide cavity, a support handle cavity, a rectangular top opening, a push button, a locking slide receiver and a sound redirection vent, wherein said push button is located on a top panel surface opposite to said locking slide receiver;
a locking slide coupled to said locking slide receiver configured to selectively toggle between a button locked position and a button free position in relation to said locking slide receiver with a linear range of motion parallel to a longitudinal axis from a top end of said enclosure body to a bottom end of said enclosure; and
a support handle coupled to said support handle cavity.

11. The mobile electronic device housing of claim 10, wherein said locking slide receiver is configured to allow said locking slide to selectively toggle by applying greater than a threshold amount of force to said locking slide along said linear range of motion.

12. The mobile electronic device housing of claim 10, wherein said support handle is coupled to said support handle cavity by a set of pivots on said support handle to a set of notches from a plurality of notches on said support handle cavity and configured to selectively toggle between a plurality of locking positions in relation to said support handle cavity,
wherein said support handle cavity is configured to allow said support handle to selectively toggle by rotating said support handle to a refracted angle,
then linearly shifting said set of pivots on said support handle to a desired notch from said plurality of notches,
then rotating said support handle to a desired angle.

13. The mobile electronic device housing of claim 10, wherein said locking slide receiver comprises at least one locking slide notch configured to secure said locking slide in said button locked position until greater than said threshold amount of force is applied.

14. The mobile electronic device housing of claim 10, wherein said housing base comprises at least one housing base peripheral opening based on the location of at least one peripheral port on a mobile electronic device.

15. The mobile electronic device housing of claim 10, wherein said support handle cavity comprises at least three (3) sets of notches corresponding to at least five (5) selectable support handle positions.

16. A method for physically limiting the use of a mobile electronic device, comprising the steps of:
coupling a housing base to a housing front panel, wherein said housing base comprises a sound redirection chamber, a locking slide cavity, and a support handle cavity, wherein said housing front panel comprises a rectangular top opening, a push button, a locking slide receiver and a sound redirection vent, wherein said push button is located on a top panel surface opposite to said locking slide receiver;
coupling a locking slide to said locking slide receiver, wherein said locking slide is configured to selectively toggle between a button locked position and a button free position in relation to said locking slide receiver with a linear range of motion parallel to a longitudinal axis from a top end of said housing front panel to a bottom end of said housing front panel, wherein said locking slide receiver is configured to allow said locking slide to selectively toggle by applying greater than a threshold amount of force to said locking slide along said linear range of motion;
coupling a support handle to said support handle cavity by fitting a set of pivots on said support handle to a set of notches from a plurality of notches on said support handle cavity, wherein said support handle is configured to selectively toggle between a plurality of locking positions in relation to said support handle cavity, wherein said support handle cavity is configured to allow said support handle to selectively toggle by rotating said support handle to a retracted angle, then linearly shifting said set of pivots on said support handle to a desired notch from said plurality of notches, then rotating said support handle to a desired angle; and
inserting a mobile electronic device between said housing base and said housing front panel.

17. The method of claim 16, wherein said front panel is removably coupled to said housing base.

18. The method of claim 16, wherein said sound redirection chamber is a hollow cavity comprising a top opening and a curved wall extending from a top-rear point of said sound redirection chamber to a bottom-front point of said sound redirection chamber, wherein said top opening is based on an exterior surface shape corresponding to a speaker portion of a mobile electronic device.

19. The method of claim 16, wherein said locking slide receiver comprises at least one locking slide notch configured to secure said locking slide in said button locked position until greater than said threshold amount of force is applied.

20. The method of claim 16, wherein said housing base comprises at least one housing base peripheral opening based on the location of at least one peripheral port on a mobile electronic device.
